(19) United States
(12) Patent Application Publication
(10) Pub. No.: US 2026/0096143 A1
(43) Pub. Date: Apr. 2, 2026

(54) METHOD OF FORMING PROTECTIVE LAYER, SEMICONDUCTOR DEVICE AND MANUFACTURING METHOD THEREOF

(71) Applicant: Taiwan Semiconductor Manufacturing Company, Ltd., Hsinchu (TW)

(72) Inventors: KUO-CHANG CHIANG, Hsinchu (TW); PO-AN CHEN, Hsinchu (TW); CHI-MIN CHEN, Hsinchu (TW); Yeh-Hsun FANG, Hsinchu (TW); Yun-Feng KAO, Hsinchu (TW); Chih-Yu CHANG, Hsinchu (TW)

(73) Assignee: Taiwan Semiconductor Manufacturing Company, Ltd., Hsinchu (TW)

(21) Appl. No.: 18/903,624

(22) Filed: Oct. 1, 2024

(51) Int. Cl. H01L 29/417; H01L 29/66; H01L 29/786

(52) U.S. Cl. CPC H10D 30/6729; H10D 30/6755; H10D 99/00

(57) ABSTRACT

A method for manufacturing a semiconductor device including the following steps is provided. A gate electrode is formed. A gate insulating layer is formed on the gate electrode. An active layer is formed on the gate insulating layer. An interface metal layer is deposited on top of the active layer, and the interface metal layer is oxidized or annealed to form a metal oxide layer on the active layer, wherein the metal oxide layer has a stronger metal-oxygen bonding than a metal-nitrogen bonding of the active layer. A dielectric layer is formed on the active layer, wherein the dielectric layer is partially etched to form two vias, and the two vias expose a portion of the active layer. A source electrode and a drain electrode are formed into the two vias respectively for electrically connecting the active layer.

### BACKGROUND

Conventional manufacturing method of a semiconductor device generates contact regions of source and drain electrodes of a thin film transistor (TFT) by chemical vapor deposition (CVD), atomic layer deposition (ALD) or physical vapor deposition (PVD). While back-end-of-line (BEOL) device is scaling down with short channel length (less than 50 nm) and reducing thickness (less than 10 nm), oxide semiconductor field effect transistors (OSFET) would suffer severe short channel effect (SCE) even by dual-layer channel stacking. In addition, such oxygen-related defects in OSFET also deteriorate the stability of threshold voltage (Vt), and will result in a decrease in the reliability of the thin film transistor, and thus it needs to have further improvements.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic diagram of a semiconductor device according to an embodiment of the present disclosure.

FIGS. 2 to 12 are schematic diagrams illustrating a method for manufacturing a semiconductor device according to an embodiment of the present disclosure.

FIG. 13 is an atomic structure diagram of a metal oxide layer and an active layer that prevents external water and hydrogen from entering according to an embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

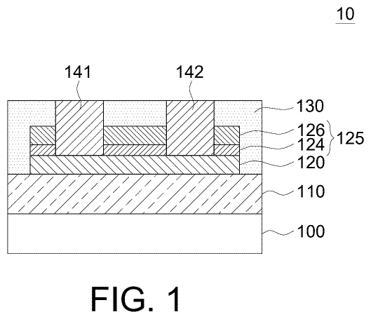

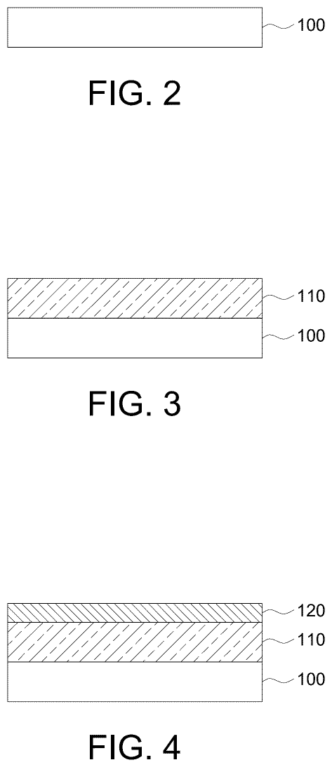

Referring to FIG. 1, FIG. 1 is a schematic diagram of a semiconductor device 10 according to an embodiment of the present disclosure. Although these embodiments take the thin film transistor having the bottom gate electrode 100 as an example, the present disclosure is not limited thereto, and can also be implemented by other embodiments. The semiconductor device 10 of FIG. 1 can be formed by the manufacturing method shown in FIGS. 2 to 12.

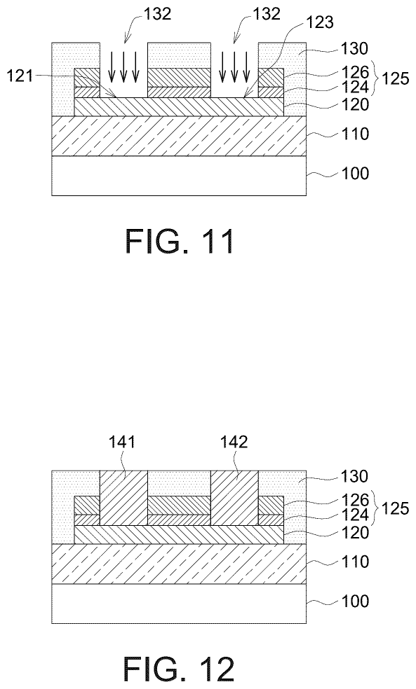

The semiconductor device 10 includes a gate electrode 100, a gate insulating layer 110, an active layer 120, a metal oxide layer 124, a capping layer 126, a dielectric layer 130, a source electrode 141 and a drain electrode 142. The gate insulating layer 110 is disposed between the gate electrode 100 and the active layer 120, the metal oxide layer 124 is disposed between the capping layer 126 and the active layer 120, and the dielectric layer 130 is disposed on the top of the capping layer 126, and the source electrode 141 and the drain electrode 142 pass through the dielectric layer 130, the capping layer 126 and the metal oxide layer 124 and are electrically connected to the active layer 120. In one embodiment, a first contact surface 121 (see FIG. 11) is formed between the source electrode 141 and the active layer 120, and a second contact surface 123 (see FIG. 11) is formed between the drain electrode 142 and the active layer 120. The metal oxide layer 124 and the capping layer 126 are configured as a protective layer 125 for the active layer 120.

The material of the gate electrode 100 is chromium (Cr), molybdenum (Mo), copper (Cu), aluminum (Al), tungsten (W), titanium (Ti) or a combination thereof, but the disclosure is not limited thereto. The gate insulating layer 110 is formed on top of the gate electrode 100. The gate insulating layer 110 may be a dielectric material including silicon oxide (SiOx), aluminum oxide (AlOx), hafnium oxide:zirconium oxide (HfOx:ZrOx), hafnium oxide:aluminum oxide (HfOx:AlOx), hafnium oxide:oxide Lanthanum (HfOx:LaOx), hafnium oxide:silicon oxide (HfOx:SiOx), hafnium oxide:strontium oxide (HfOx:SrO), hafnium zirconium oxide (HZO) doped with cerium oxide (CeOx), etc.

One common gate insulating layer 110 is silicon oxide. While a thinner silicon oxide gate dielectric is also more susceptible to tunneling and has a greater gate leakage. In addition, high-k gate dielectric has been introduced into field effect transistors (FETs) for better transistor performance and the demand of low operation voltage. The high-k gate dielectric may be hafnium oxide (HfOx), hafnium zirconium oxide (HZO) or other dielectrics with a dielectric constant more than 6. While any suitable gate dielectric may be used, many examples of the present disclosure use a high-k gate dielectric as the gate insulating layer 110 to reduce leakage current, reduce threshold voltage, and/or optimize the operation of the transistor.

The active layer 120 is formed on top of the gate insulating layer 110, and the material of the active layer 120 includes monocrystalline silicon (a-Si), polycrystalline silicon (poly-Si) or metal oxide semiconductor or metal oxynitride semiconductor.

In some embodiments, the metal oxynitride semiconductor comprises at least one of In, Ga, and Zn. Other elements can be selected among Ti, Al, W, Ce, Sn, Zr, Nd, Sm and Lu for addition formation element of metal oxynitride semiconductor.

FIGS. 2 to 12 show schematic diagrams illustrating a method for manufacturing the semiconductor device 10 according to an embodiment of the present disclosure. The method for manufacturing the semiconductor device 10 includes the following steps. In FIG. 2, a gate electrode 100 is formed. For example, in the formation process of the gate electrode 100, metals such as aluminum (Al) and copper (Cu) with low resistivity, or molybdenum (Mo), chromium (Cr), titanium (Ti) with high heat resistance or one of the alloys of these metals are preferably selected.

In addition, the gate electrode 100 may be a laminated gate electrode including multiple layers of metals, and the thickness of the gate electrode 100 may be 50-500 Å. The gate electrode 100 may be composed of metal composites, such as WN, TiN, or TaN. The specific material(s) used depend upon the desired work function of the gate and the type of semiconductor devices.

In FIG. 3, a gate insulating layer 110 is formed on top of the gate electrode 100. In the formation of the gate insulating layer 110, oxides such as HfOx or HZO can be selectively used. The multilayer insulating film can increase the dielectric constant. Therefore, the total film thickness of the multilayer gate insulating layer 110 can be reduced. In FIG. 3, although the gate insulating layer 110 is shown as a single layer, the gate insulating layer 110 may include multiple insulating layers, and each insulating layer may include a different dielectric material.

In FIG. 4, an active layer 120 is formed on the gate insulating layer 110. The active layer 120 is, for example, a nitrogen-doped oxide semiconductor (so called oxynitride semiconductor or ONS), which can be formed by, for example, direct current (DC) sputtering or radio frequency (RF) sputtering. In the DC sputtering or RF sputtering, a sputtering target having the same composition as the oxide semiconductor of the active layer 120. Alternatively, the active layer 120 may be formed by a co-sputtering method using a plurality of sputtering targets (i.e., targets with Ar/O₂/N₂ gas flow, N at 1-10%), CVD, ALD (with NH₃ gas precursor), or PVD.

However, oxynitride semiconductor (ONS) device still reveals several drawbacks that must be addressed, including poor Vt instability when exposed to air and nitrogen-rich induced vacancy (V_{N}) for the source of electrons and additional carrier traps. These issues are attributed to the fact that the metal-nitrogen bonding is weaker than the metal-oxygen bonding, leading to nitrogen to be placed by oxygen and the out-diffusion of nitrogen again.

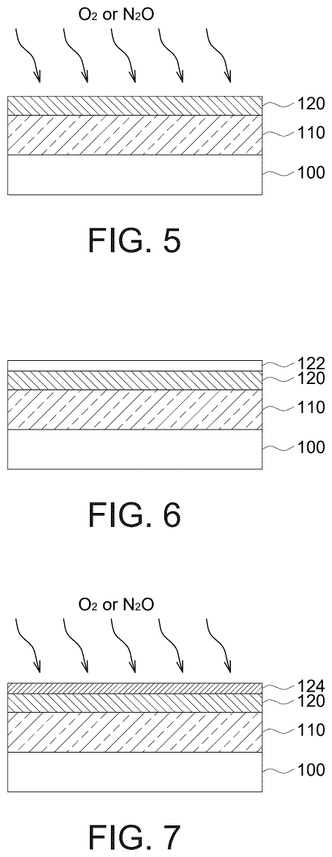

Referring to FIG. 5, in one embodiment, the active layer is oxidized or annealed, for example, oxygen is introduced or N₂O treatment is performed at a Celsius temperature between 150 degrees and 350 degrees. N₂O plasma treatment can form an oxygen-rich, low carrier concentration interface layer at the interface, which can effectively repair ONS device being damaged and resist the influence of passivation layer deposition. After N₂O plasma treatment, the proportion of oxygen vacancies in the film decreased, indicating that the oxygen vacancy concentration in the film decreased to a certain extent. Since oxygen vacancies in metal oxide semiconductors are a major source of carriers, the carrier concentration in the film will be reduced to a certain extent.

Referring to FIG. 6, an interface metal layer 122 is deposited on top of the active layer 120. The interface metal layer can be Al, Ti, Ta, Lu, Te, La, and the like. The thickness of the interface metal layer 122 is about 0.5 to 5 nm, and the interface metal layer 122 is formed by, for example, CVD, ALD or PVD. Referring to FIG. 7, the interface metal layer 122 is oxidized or annealed, for example, oxygen is introduced or N₂O treatment is performed on the interface metal layer 122 at a Celsius temperature between 150 degrees and 350 degrees to form a metal oxide layer 124 on the active layer 120. The metal oxide layer 124 would keep amorphous-like phase after thermal treatment at a Celsius temperature between 150 and 350 degrees, and a clear heterointerface can be formed between the active layer 120 and the metal oxide layer 124.

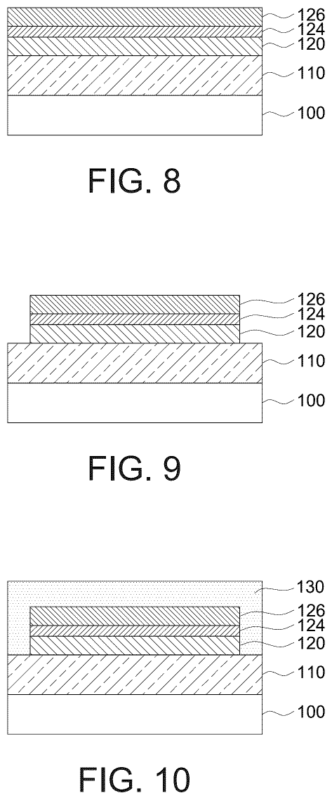

Referring to FIG. 8, a capping layer 126 is deposited on top of the metal oxide layer 124. In the formation of the capping layer 126, oxides such as SiOx, TiOx, AlOx, or HfOx can be selectively used, and a multilayer type in which a SiOx thin film and a TiOx thin film are continuously formed can be used as the capping layer 126, for example. The capping layer 126 is formed by CVD, ALD or PVD, for example. Other oxides, for example, zinc oxide (ZnO), gallium oxide (GaO), indium oxide (InO), and nickel oxide (NiO) can be selectively used, which have high bonding force with oxygen ions and can prevent oxygen ions from being bombarded by plasma and released (i.e., bond breaking). The thickness of the capping layer 126 may be between 10 Å and 200 Å, but it is not limited in the present disclosure.

Next, referring to FIG. 9, the capping layer 126, the metal oxide layer 124 and the active layer 120 are patterned and etched to form a protruding structure including the capping layer 126, the metal oxide layer 124 and the active layer 120. Referring to FIG. 10, a dielectric layer 130 surrounds the top surface and sidewalls of the capping layer 126, the metal oxide layer 124 and the active layer 120. The dielectric layer 130 may be SiOx, SiON, SiN, high-k dielectrics (e.g., HFO₂, Al₂O₃, TiO₂) or the like. The dielectric layer 130 is formed by, for example, CVD, ALD or PVD.

Referring to FIG. 11, the dielectric layer 130, the capping layer 126 and the metal oxide layer 124 are partially etched by plasma to form two vias 132, and the two vias 132 expose a portion of the active layer 120. The exposed portion of the active layer 120 serves as two contact surfaces 121 and 123 for connecting the source electrode 141 and the drain electrode 142 subsequently deposited therein (see FIG. 12.).

Referring to FIG. 12, the source electrode 141 and the drain electrode 142 are formed in the two vias 132 by CVD□ALD or PVD deposition. A channel region is formed between the source electrode 141 and the drain electrode 142, and the gate electrode 100 is disposed under the channel region for applying a gate voltage to control the current flowing through the channel. The types of the source electrode 141 and the drain electrode 142 are not particularly limited, and common electrode materials can be used. For example, the source electrode 141 and the drain electrode 142 may be made by one of TaN, TiN, Molybdenum (Mo), Tungsten (W), Titanium (Ti) and the like or alloys.

The formation method of the source electrode 141 and the drain electrode 142 is not limited, for example, a metal film is formed by a magnetron sputtering method or a radio frequency (RF) sputtering method, and then a wet etching is performed with an etchant of hydrogen peroxide, phosphoric acid, nitric acid or acetic acid to remove a portion of the metal film above the dielectric layer 130, thereby forming the source electrode 141 and the drain electrode 142.

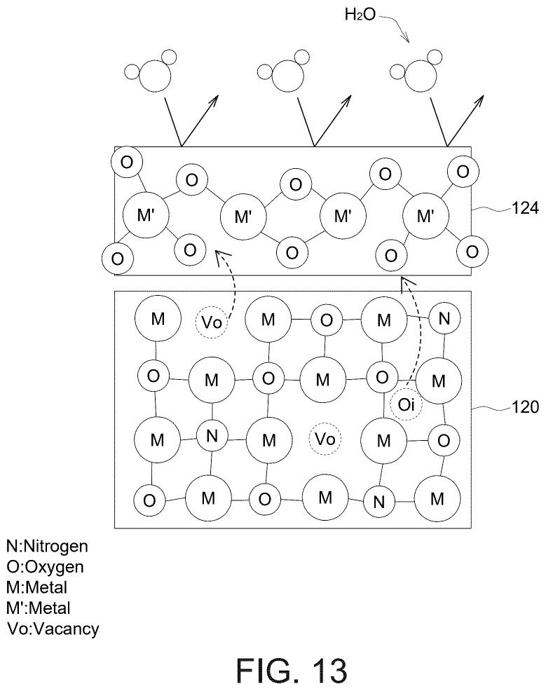

Please refer to FIG. 13, the metal oxide layer 124 can avoid plasma damage to the active layer 120 caused by the plasma gas. In addition, the metal oxide layer 124 serves the passivation effect from water and hydrogen absorption. Such metal oxide layer 124 enables to stabilize the weak metal-nitrogen bonding of the active layer 120 and suppress out-diffusion of nitrogen by stronger metal-oxygen bonding of the metal oxide layer 124.

In addition, as shown in FIG. 13, the interstitial oxygen (Oi) in the active layer 120 can also be bonded with the metal oxide layer 124, thereby reducing the generation of oxygen-related deficiencies (e.g., oxygen vacancy Vo) and reliability deterioration. Therefore, the metal oxide layer 124 not only prevents the external water (H₂O) or hydrogen from diffusing into the active layer 120, but also stabilizes the metal-nitrogen (M—N) bonding to reduce the formation of internal metal-oxygen-nitrogen (M—Oₓ—N₁₋ₓ) defect state.

The metal oxide layer 124 also possess a higher band gap (>4.5 eV), which creates a high barrier for electron transfer, resulting in a small negative delta Vt shift (<100mV) of potential SCE on the top surface of the active layer 120. Moreover, these high valence state of cations (e.g., Ta⁵⁺, Te⁵⁺, Ti⁴⁺, Al³⁺, Lu³⁺, La³⁺ and the like) can create the donor-like vacancy defect at the interface between the metal oxide layer 124 and the active layer 120, inducing the on-current boost by constrained two dimensional electron gas (2DEG) region without reliability penalties. Thus, ion boost by 2DEG would result in the increment of electron amount, leading Fermi energy level toward Ec, where Ec is the minimum energy of the conduction band.

The present disclosure relates to a method of forming a protective layer on a semiconductor device, the semiconductor device and a manufacturing method thereof for improving the reliability of the semiconductor device. Based on the present disclosure, ONSFET with the advantage of low temperature process are widely used as the BEOL compatible device. Reliability of ONSFET is contributed by stable ONS layer quality with defect suppression during operation. Due to underlying process damage or high defect density at the interface between the dielectric layer and ONS layer, oxygen vacancies and the formation of leakage paths into the ONS channel are generated. Therefore, a capping metal oxide layer is formed on the surface of ONS layer and then be oxidized by thermal treatment to serve passivation effect from water and hydrogen absorption. Such metal oxide layer enables to stabilize the weak metal-nitrogen bonding of the ONS layer and suppress out-diffusion of nitrogen by stronger metal-oxygen bonding of the metal oxide layer.

In some embodiments of the present disclosure, a semiconductor device is provided. The semiconductor device includes a gate electrode, a gate insulating layer, an active layer, a metal oxide layer, a dielectric layer, a source electrode and a drain electrode. The gate insulating layer is disposed between the gate electrode and the active layer. The metal oxide layer is disposed on top of the active layer, wherein the metal oxide layer has a stronger metal-oxygen bonding than a metal-nitrogen bonding of the active layer. The dielectric layer is disposed on a side of the active layer and the metal oxide layer. The source electrode and the drain electrode pass through the dielectric layer and the metal oxide layer for electrically connecting to the active layer.

In some embodiments of the present disclosure, a method for manufacturing a semiconductor device is provided, which includes the following steps. A gate electrode is formed. A gate insulating layer is formed on the gate electrode. An active layer is formed on the gate insulating layer. An interface metal layer is deposited on top of the active layer, and the interface metal layer is oxidized or annealed to form a metal oxide layer on the active layer, wherein the metal oxide layer has a stronger metal-oxygen bonding than a metal-nitrogen bonding of the active layer. A dielectric layer is formed on the active layer, wherein the dielectric layer is partially etched to form two vias, and the two vias expose a portion of the active layer. A source electrode and a drain electrode are formed into the two vias respectively for electrically connecting the active layer.

In some embodiments of the present disclosure, a method of forming a protective layer on a semiconductor device is provided, which includes the following steps. An interface metal layer is deposited on top of an active layer of the semiconductor device, and the interface metal layer is oxidized or annealed to form a metal oxide layer on the active layer, wherein the metal oxide layer has a stronger metal-oxygen bonding than a metal-nitrogen bonding of the active layer. A capping layer is formed on top of the metal oxide layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device comprising:
a gate electrode;
a gate insulating layer;
an active layer, wherein the gate insulating layer is disposed between the gate electrode and the active layer;
a metal oxide layer disposed on top of the active layer, wherein the metal oxide layer has a stronger metal-oxygen bonding than a metal-nitrogen bonding of the active layer;
a dielectric layer disposed on a side of the active layer and the metal oxide layer;
a source electrode; and
a drain electrode, wherein the source electrode and the drain electrode pass through the dielectric layer and the metal oxide layer for electrically connecting to the active layer.

2. The semiconductor device according to claim 1, wherein the metal oxide layer comprises at least one of Al, Ti, Ta, Lu, Te, and La.

3. The semiconductor device according to claim 1, wherein the active layer is a metal oxynitride semiconductor comprising a material selected from at least one of In, Ga, and Zn.

4. The semiconductor device according to claim 1, further comprising a capping layer disposed on top of the metal oxide layer.

5. The semiconductor device according to claim 4, wherein the capping layer comprises a material of SiOx, TiOx, AlOx, HfOx or a combination thereof.

6. The semiconductor device according to claim 4, wherein the dielectric layer surrounds a top surface and sidewalls of the capping layer and the metal oxide layer.

7. The semiconductor device according to claim 6, wherein the dielectric layer comprises a material of SiOx, HFO2, Al2O3, TiO2 or a combination thereof.

8. The semiconductor device according to claim 1, wherein the source electrode and the drain electrode comprise a material of TaN, TiN, Mo, W, Ti or a combination thereof.

9. A method for manufacturing a semiconductor device, comprising:
forming a gate electrode;
forming a gate insulating layer on the gate electrode;
forming an active layer on the gate insulating layer;
depositing an interface metal layer on top of the active layer, and the interface metal layer is oxidized or annealed to form a metal oxide layer on the active layer, wherein the metal oxide layer has a stronger metal-oxygen bonding than a metal-nitrogen bonding of the active layer;
forming a dielectric layer on the active layer, wherein the dielectric layer is partially etched to form two vias, and the two vias expose a portion of the active layer; and
forming a source electrode and a drain electrode into the two vias respectively for electrically connecting the active layer.

10. The method according to claim 9, wherein before depositing the interface metal layer on top of the active layer, a first oxidization treatment or annealing treatment on the active layer is performed at a Celsius temperature between 150 degrees and 350 degrees.

11. The method according to claim 10, wherein after depositing the interface metal layer on top of the active layer, a second oxidization treatment or annealing treatment on the interface metal layer is performed at a Celsius temperature between 150 degrees and 350 degrees.

12. The method according to claim 9, wherein the metal oxide layer comprises at least one of Al, Ti, Ta, Lu, Te, and La.

13. The method according to claim 9, wherein the active layer is a metal oxynitride semiconductor comprising a material selected from at least one of In, Ga, and Zn.

14. The method according to claim 9, further comprising forming a capping layer on top of the metal oxide layer.

15. The method according to claim 14, wherein the capping layer comprises a material of SiOx, TiOx, AlOx, HfOx or a combination thereof.

16. A method of forming a protective layer on a semiconductor device, comprising:
depositing an interface metal layer on top of an active layer of the semiconductor device, and the interface metal layer is oxidized or annealed to form a metal oxide layer on the active layer, wherein the metal oxide layer has a stronger metal-oxygen bonding than a metal-nitrogen bonding of the active layer; and
forming a capping layer on top of the metal oxide layer.

17. The method according to claim 16, wherein before depositing the interface metal layer on top of the active layer, a first oxidization treatment or annealing treatment on the active layer is performed at a Celsius temperature between 150 degrees and 350 degrees.

18. The method according to claim 17, wherein after depositing the interface metal layer on top of the active layer, a second oxidization treatment or annealing treatment on the interface metal layer is performed at a temperature between 150 Celsius degrees and 350 degrees.

19. The method according to claim 16, wherein the metal oxide layer comprises at least one of Al, Ti, Ta, Lu, Te, and La.

20. The method according to claim 16, wherein the active layer is a metal oxynitride semiconductor comprising a material selected from at least one of In, Ga, and Zn.
